(19) United States
(12) Patent Application Publication
(10) Pub. No.: US 2011/0103030 A1
(43) Pub. Date: May 5, 2011

(54) Packages and Methods for Mitigating Plating Stub Effects

(75) Inventors: Moises Cases, Austin, TX (US); Tae Hong Kim, Austin, TX (US); Bhyrav M. Mutnury, Austin, TX (US); Nanju Na, Essex Junction, VT (US)

(73) Assignee: International Business Machines Corporation, Armonk, NY (US)

(21) Appl. No.: 12/610,413

(22) Filed: Nov. 2, 2009

(51) Int. Cl. H01L 23/52; H01L 21/60; H05K 7/00

(52) U.S. Cl. 361/782; 438/121; 257/692; 257/724; 257/E23.141; 257/E21.509

(57) ABSTRACT

Packages and methods for mitigating plating stub effects. The semiconductor package includes an interposer substrate having a first side, a second side, a peripheral edge connecting the first side with the second side, a signal line on the first side, and an electrode pad on the first side. A semiconductor element is mounted on the first side of the interposer substrate. The semiconductor element is connected with the electrode pad by the signal line. A terminating resistor is mounted on the interposer substrate. A plating stub, which is located on the interposer substrate, has a first end portion that terminates near the peripheral edge of the interposer substrate and a second end portion that is electrically connected to the electrode. The first end portion is electrically connected through the terminating resistor to an electrical ground.

### BACKGROUND

The present invention relates to semiconductor fabrication and, in particular, to semiconductor packages having a semiconductor element mounted thereon, for transferring a high-speed signal, and particularly to the wiring configuration on an interposer substrate of the device package.

Integrated circuit (“IC”) packaging is the final stage of semiconductor device fabrication per se, followed by IC testing. Contemporary electronic apparatuses include components that transmit very high-speed signals having a pulse width that corresponds, after being converted to frequency domain, to several hundreds of megahertz to one gigahertz. As technology advances, these signal speeds have been increased even more, and there is a demand for the transmission of a signal that corresponds to a frequency of several gigahertz or higher.

Further, multifunctional ICs and IC modules have been developed that are like system large scale integration (“LSI”) chips, and these ICs are mounted in multi-terminal packages, such as ball grid arrays (“BGA”) or chip scale packages (“CSP”). That is, an IC having a high-speed signal transmission interface tends to be mounted in a multi-terminal semiconductor package, such as a BGA or a CSP. Ball grid array packages and their variants have existed since the 1970s. The BGA is descended from the pin grid array (“PGA”), which is a package with one face covered (or partly covered) with pins in a grid pattern. These pins are used to conduct electrical signals from the integrated circuit to the printed circuit board (“PCB”) on which it is placed. In a BGA, the pins are replaced by balls of solder stuck to the bottom of the package. The device is placed on a PCB that carries copper pads in a pattern that matches the pattern of solder balls. The assembly is then heated, either in a reflow oven or by an infrared heater, causing the solder balls to melt. Surface tension causes the molten solder to hold the package in alignment with the circuit board, at the correct separation distance, while the solder cools and solidifies.

Generally, in a semiconductor package, a semiconductor element is connected by wire bonding to electrode pads on a resin substrate (an interposer) on which the semiconductor element is mounted. These electrode pads are connected to the interposer by signal lines that extend radially on the interposer. The electrode pads are also connected through vias to ball pads that are provided on the reverse face of the interposer, which connect to the solder balls of the BGA to attach the semiconductor package to a motherboard or other type of PCB.

Gold plating is typically required for the electrode pads on the interposer. In order to perform the gold plating for the electrode pads, the electrode pads must be rendered conductive from the outer edge of the interposer. Therefore, in addition to wiring connected to the mounted semiconductor element, other wiring is extended from the outer edge of the interposer to the individual electrode pads. Wiring extended from an individual electrode pad to the outer edge of the interposer is called a “plating stub”. Plating stubs have an open end at the outer edge of the interposer, along the transmission line. The length of these stubs is generally about 1 to 4 mm for a BGA package, of a peripheral type, with 1 mm pitches and four rows. However, the stub length may be increased as package sizes grow with higher I/O count and ball array row count.

When a period during which a signal reciprocates along a signal line in the open state is longer than the rise time for the signal, a reflected waveform occurs in the signal waveform and causes waveform distortion. For a signal for which the waveform is trapezoidal, the rise time for the signal is generally equal to about 5% of the cycle. Therefore, for a conventionally employed signal having a frequency of 1 GHz, the cycle is about 1.0 nsec and the rise time, which is 5% of the cycle, is 0.050 nsec. Through a calculation performed by employing a signal transfer rate of 6 nsec/m for a common glass epoxy substrate, the equivalent length obtained, for both directions is 8.30 mm, and the wiring length obtained that corresponds to one direction is 4.15 mm. That is, in the open state, a plating stub of about 1 to 4 mm in length does not greatly affect the quality of the waveform.

The frequency of a signal used for the semiconductor element has been repeatedly increased, and a signal having a frequency even greater than 2 GHz is now employed. For a signal having a frequency of 2 GHz, the cycle is 0.5 nsec and the rise time, which is 5% of the cycle, is 0.025 nsec. Through calculations performed using the signal transfer rate of 6 nsec/m, the equivalent length in both directions is 4.15 mm, and the wiring length corresponding to one direction is 2.08 mm. That is, in the open state, a plating stub of about 2 mm or longer would greatly affect the waveform of a signal to be transmitted.

A differential transmission method may be adopted for high-speed signals. A differential pair of signal lines for which impedance matching is required must be provided on the interposer. In order to achieve impedance matching for the differential pair of signal lines, a predetermined clearance must be maintained between two signal lines of a differential pair of signal lines. However, it is challenging, while maintaining this clearance, for the differential pair of signal lines to be passed through a number of electrode pads and connected to the electrode pads nearest the outer edge of the interposer substrate. Inner row ball assignment is preferred from a perspective of low package loss rather than a perspective of impedance matching if the plating stub is not a concern, but from a board escape perspective, these differential signal assignments are preferred on outer ball rows. However, in practical link density applications, all rows are considered for high speed signal assignment, causing the lengths of the plating stubs to increase. Thus with the increased lengths of the plating stubs, the distortion of waveforms for signals to be transmitted cannot be avoided. Additionally, even relative short stubs of the outer row ball signals are now starting to make a sizeable impact on the signals as the speed increases toward 10 giga-bit per second and beyond.

What is needed therefore is a method and a semiconductor package to mitigate the distortion of the waveforms for the transmitted signals.

### BRIEF SUMMARY

According to one embodiment of the invention, a semiconductor package includes an interposer substrate having a first side, a second side, a peripheral edge connecting the first side with the second side, a signal line on the first side, and an electrode pad on the first side. A semiconductor element is mounted on the first side of the interposer substrate, where the semiconductor element is connected with the electrode pad by the signal line. A plating stub is located on the interposer substrate. The plating stub has a first end portion electrically connected through a terminating resistor to a ground, where the terminating resistor is mounted on the interposer substrate. The first end portion of the plating stub terminates near the peripheral edge of the interposer substrate. The second end portion of the plating stub is electrically connected to the electrode pad.

In some embodiments of the semiconductor package, the terminating resistor includes a resistor having a first end electrically connected to the first end portion of the plating stub and a second end electrically connected to ground. In these embodiments, the resistor may be a surface mounted resistor or a resistive film. The resistor may have a resistance in a range of 40 ohms to 300 ohms. In a specific embodiment, the plating stub is located on the first side of the interposer substrate and the terminating resistor is mounted on the first side of the interposer substrate. In an alternative embodiment, the plating stub is located on the second side of the interposer substrate and electrically connected to the signal line by a via extending through the interposer substrate. In this embodiment the terminating resistor is mounted on the second side of the interposer substrate.

In other embodiments of the semiconductor package the electrode pad is a first electrode pad and the signal line is a first signal line. The second side of the semiconductor package contacts a ball grid array (BGA) containing a plurality of solder balls. In these embodiments, the semiconductor package further includes a second electrode pad connected to the second end of the resistor by a second signal line. The second electrode pad is further connected to a grounded solder ball of the plurality of solder balls in the ball grid array on the second side of the interposer substrate by a via extending through the interposer substrate from the first side to the second side.

According to another embodiment of the invention, a system includes a motherboard and a semiconductor package. The semiconductor package is electrically connected to the motherboard. The semiconductor package includes an interposer substrate having a first side, a second side, a peripheral edge connecting the first side with the second side, a signal line on the first side, and an electrode pad on the first side. A semiconductor element is mounted on the first side of the interposer substrate, where the semiconductor element is connected with the electrode pad by the signal line. A plating stub is located on the interposer substrate. The plating stub has a first end portion electrically connected through a terminating resistor to a ground, where the terminating resistor is mounted on the interposer substrate. The first end portion of the plating stub terminates near the peripheral edge of the interposer substrate. The second end portion of the plating stub is electrically connected to the electrode pad.

According to another embodiment of the invention, a method of mounting a semiconductor element on an interposer substrate having a first side, a second side, a peripheral edge connecting the first side with the second side, a signal line on the first side and an electrode pad on the first side, includes connecting the electrode pad with the semiconductor element by the signal line. In these embodiments, the method further includes electrically connecting a first end portion of a plating stub to the electrode pad and electrically connecting a second end portion of the plating stub, which terminates near an edge of the interposer substrate, through a terminating resistor to ground, where the terminating resistor is mounted on the interposer substrate. This method enables wirebond packaging with plating process to carry higher speed signals which otherwise cannot be accommodated in this type of package.

### BRIEF DESCRIPTION OF THE SEVERAL VIEWS OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIG. 1 is a schematic perspective view of a semiconductor package mounted on a motherboard in accordance with an embodiment of the invention.

FIG. 2 is a detailed perspective view of the semiconductor package of FIG. 1.

FIG. 3 is a schematic top view of the semiconductor package of FIG. 2.

FIG. 4 is a schematic top view of a semiconductor package with a single trace in accordance with an alternative embodiment of the invention.

FIGS. 5A-5G are diagrammatic views illustrating successive stages of a masking and etching process used to generate resistive films that can be utilized with the embodiments in FIGS. 1-4.

FIG. 6 is a graphical view of signal loss over a frequency range.

FIG. 7 is a perspective view of a semiconductor package in accordance with an alternative embodiment of the invention.

It should be understood that the appended drawings are not necessarily to scale, presenting a somewhat simplified representation of various preferred features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

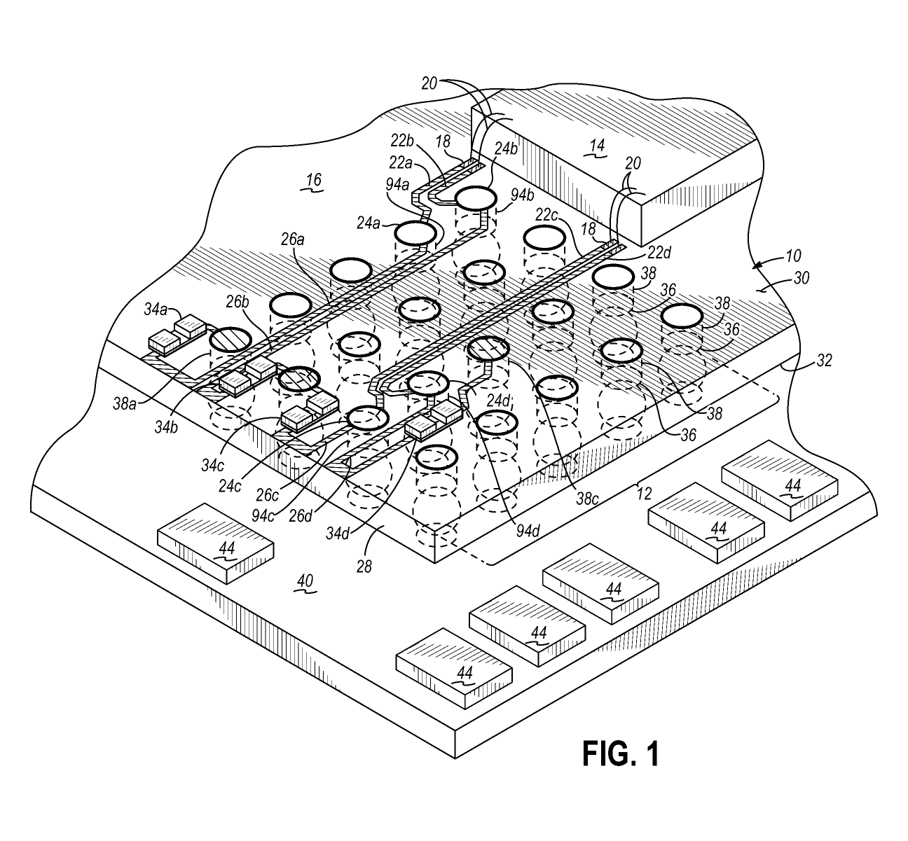

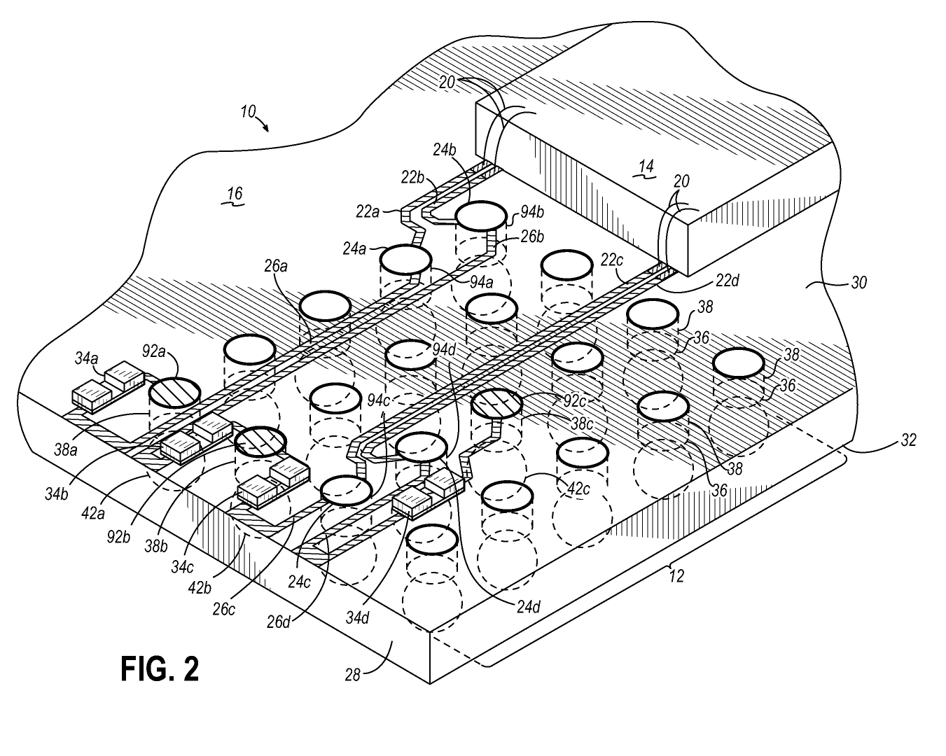

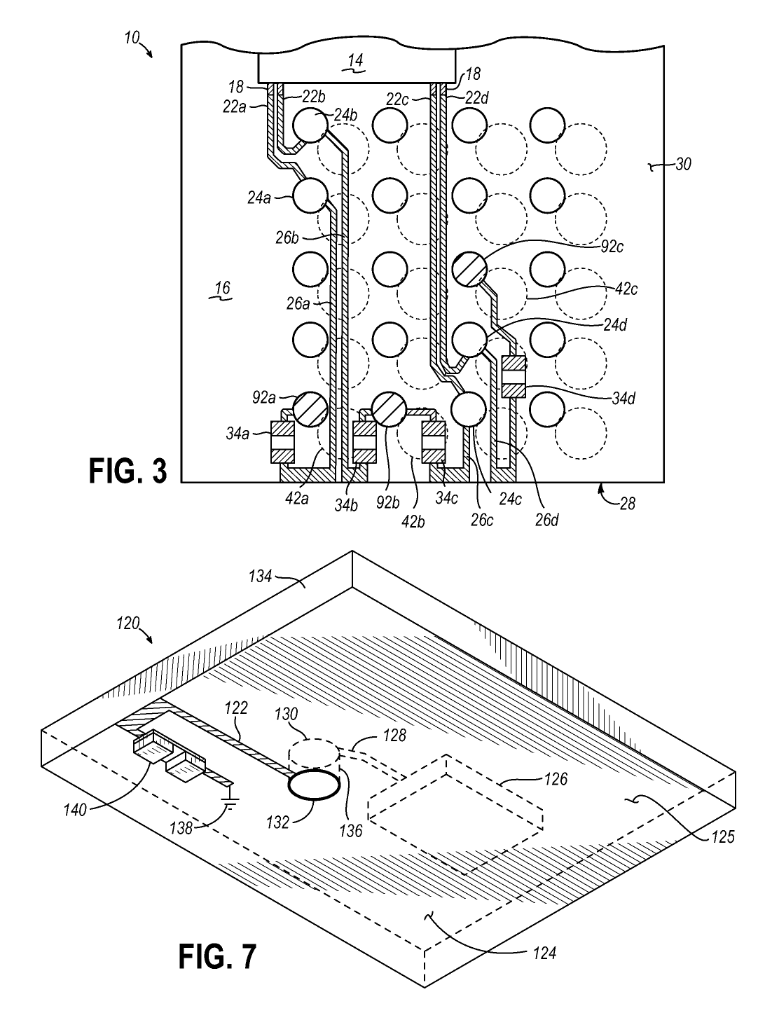

FIGS. 1-3 illustrate an exemplary semiconductor package 10 configured with a ball grid array (“BGA”) 12. A semiconductor element 14 is mounted on one side 30 of an interposer substrate 16, which provides mechanical support to the semiconductor element 14. The interposer substrate 16 is composed of an electrically insulating dielectric material, such as polyimide, and may be either a flexible sheet or a more rigid plate. Bond wires 20, such as flexible lengths of gold wire, are used to electrically connect the semiconductor element 14 to electrode terminals 18 on the interposer substrate 16. The interposer substrate 16 includes electrode pads 24a, 24b, 24c, 24d and signal lines 22a, 22b, 22c, 22d that electrically connect the electrode terminals 18 to the electrode pads 24a-d. Generally, the length of the signal lines 22a-d is shorter for higher frequency signals, although the length is also subject to matching the pattern of the BGA 12.

The interposer substrate 16 further includes plating stubs 26a, 26b, 26c, 26d that extend from the electrode pads 24a-d to a peripheral edge 28 of the interposer substrate 16. The peripheral edge 28 connects and extends between the opposite sides 30, 32 of the interposer substrate 16. The signal lines 22a-d, electrode pads 24a-d, and plating stubs 26a-d are all located on the same side 30 of the interposer substrate 16.

As described above, the plating stubs 26a-d render the electrode pads 24a-d conductive to the outer peripheral edge 28 of the interposer 16. Each of the plating stubs 26a-d has an open end along the transmission line at the peripheral edge 28 of the interposer substrate 16. If unmitigated, the open end of each plating stub 26a-d may be a significant source of interference to the signals transmitted along the signal lines 22a-d because of signal reflections in the plating stubs 26a-d. Accordingly, terminating resistors 34a, 34b, 34c, 34d are provided at the open ends of the plating stubs 26a-d in order to mitigate, alleviate, or otherwise reduce the interference from signal reflections.

Ball pads 36 are arranged in a grid or array on the reverse side 32 of the interposer substrate 16. Electrically-conductive vias 38, including vias 38a-c, extend through the entire thickness of the interposer substrate 16 between the opposites sides 30, 32. The electrode pads 24a-d are connected to the ball pads 36 by the vias 38 formed in the interposer substrate 16. The ball pads 36 are attached to a motherboard 40, or other type of printed circuit board (“PCB”), via solder balls 42, including the representative solder balls 42a-c, of the BGA 12. The solder balls 42 may then connect to metallic contact pads 44 on the motherboard 40. The metallic pads 44 are present in a grid or array pattern that matches the grid or array pattern of the solder balls on the backside of the package 10, including solder balls 42a-c that represent ground connections. Vias 38a-c connect solder balls 42a-c with respective electrode pads 92a, 92b, 92c. The signal lines 22a-d are also respectively connected to electrode pads 24a-d, which are connected through vias 94a, 94b, 94c, 94d to other solder balls 42 in the BGA 12.

The assembly of package 10 and motherboard 40 is heated, either in a reflow oven or by an infrared heater, causing the solder balls 42a-c to melt. Surface tension causes the molten solder of the solder balls 42a-c to hold the package 10 in alignment with the motherboard 40, at the correct separation distance, while the solder cools and solidifies to form physical connections between the vias 38 and the metallic pads 44. The resulting physical connections electrically interconnect the package 10 with the motherboard 40.

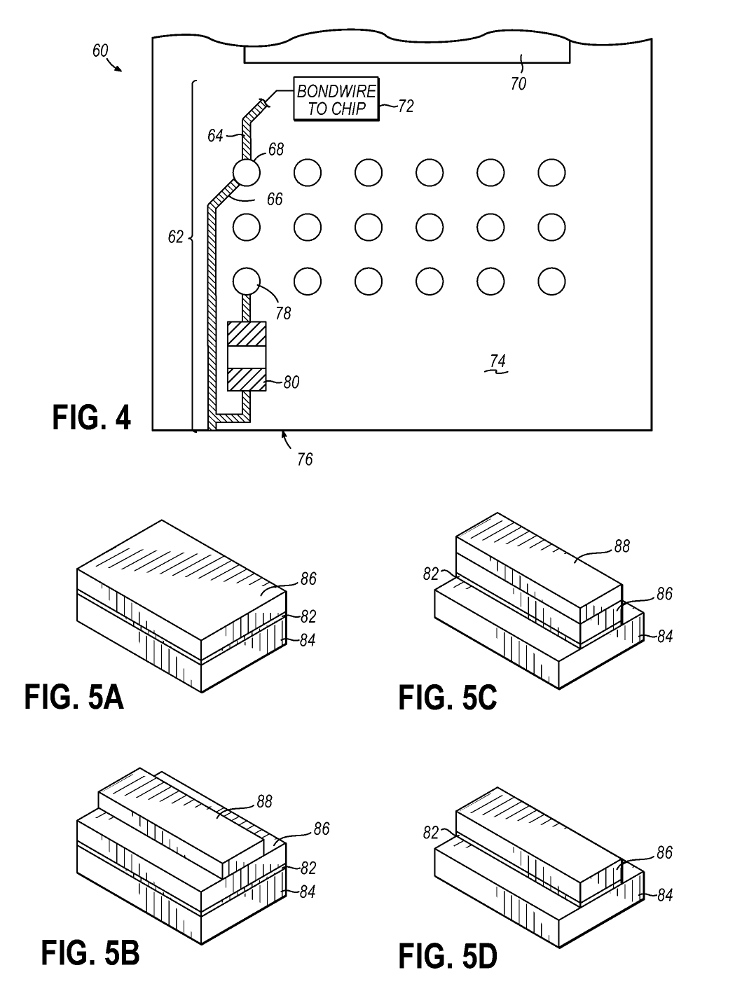

FIG. 4 is a diagrammatic view of a semiconductor package 60 illustrating a single conductor 62 consisting of a high frequency signal line 64 and a plating stub 66 intersected by an electrode pad 68. The signal line 64 is electrically connected to the semiconductor element 70 via a bondwire 72. Electrode pad 68 is electrically connected to a pad (not shown) on the opposite side of the interposer substrate 74 through a via (not shown). The pad on the opposite side of the interposer substrate 74 may then be connected to a ball grid (not shown) which in turn connects to a motherboard (not shown) similar to the package substrate illustrated in FIG. 1. The plating stub 66 extends from the electrode pad 68 to the peripheral edge 76. To reduce interference due to reflections in the plating stub 66, the stub 66 is electrically connected to an electrode pad 78, which is connected to ground, through a terminating resistor 80.

In a representative embodiment, each terminating resistor 34a-d (FIGS. 1-3) or the terminating resistor 80 (FIG. 4) may be a surface mount resistor that is added during the assembly process and after the design and manufacturing are complete. Such surface mount resistors are directly attached onto side 30 of the interposer substrate 16.

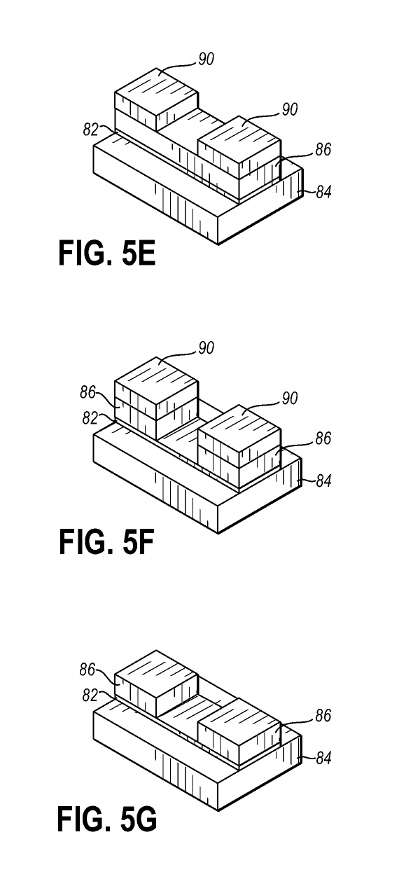

In an alternative embodiment, each terminating resistor 34a-d (FIGS. 1-3) or the terminating resistor 80 (FIG. 4) may be a resistive film, which then may be included as part of the overall design and manufacturing process for the packaging. These resistive films may be formed using a masking and etching process as is well known to a person having ordinary skill in the art. For example, in FIG. 5A, a resistive film 82 is applied to a dielectric substrate 84, such as the interposer substrate 16 in FIGS. 1-3 or the interposer substrate 74 in FIG. 4. The resistive film 82 is then covered by an electrodeposited copper foil 86. In FIG. 5B, a photoresist layer 88 is applied over the area that is destined to become the resistor, such as terminating resistors 34a-d (FIGS. 1-3) or terminating resistor 80 (FIG. 4). The dielectric substrate 84 is then subjected to an etching process where excess material, which is not masked by the photoresist layer 88, is removed as seen in FIG. 5C. The photoresist layer 88 is stripped off in FIG. 5D with, for example, a chemical solvent or plasma ashing.

A second photoresist layer 90 is applied over the copper foil in FIG. 5E to define an area of the conductive pads for the terminating film resistor. A second etch step is shown in FIG. 5F in which the copper foil 86 is removed to expose the resistive film 82 in areas not masked by the photoresist layer 90. Finally in FIG. 5G, the residual photoresist layer 90 is stripped off leaving the terminating resistor that includes the resistive film 82 and conductive end pads of the remaining copper foil 86.

With renewed reference to FIGS. 1-4, while the terminating resistor 80 may be used to terminate the plating stub 66 extending from the signal line 64 or each of the terminating resistors 34a-d may be used to terminate the plating stubs 26a-d extending from one of the signal lines 22a-d, a person having ordinary skill in the art will appreciate that lower frequency signals will have longer wavelengths. Because of the longer wavelengths, it may not be necessary to use terminating resistors 34a-d, 80 on these signal lines 22a-d, 64.

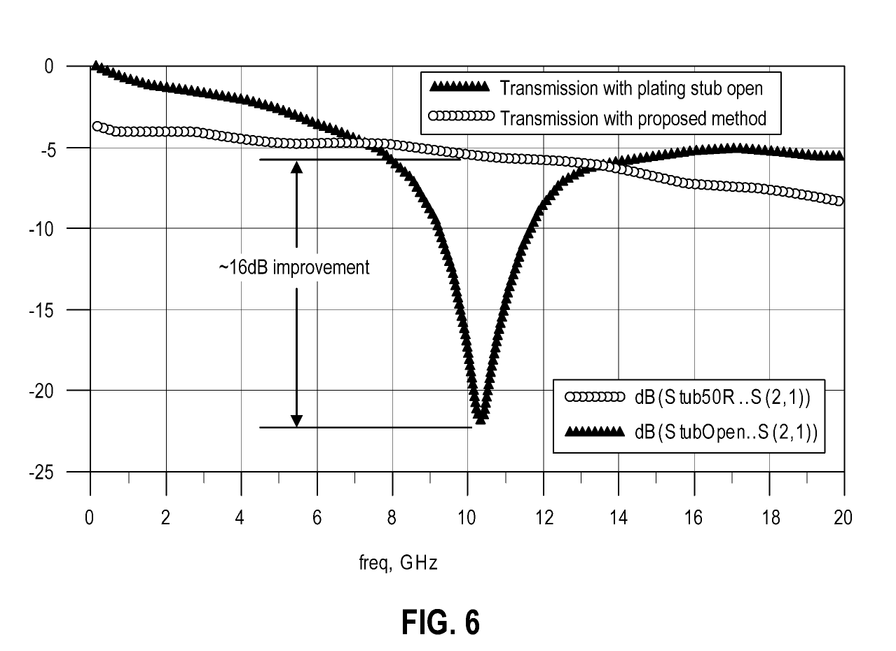

The resistance of each of the terminating resistors 34a-d, 80 may generally be in the range of 30 ohms to 350 ohms, preferably 40 ohms to 300 ohms. The exact resistance value will depend, among other factors, on the frequency range of the signals on the signal lines such as signal lines 22a-d or signal line 64. As apparent from the curves on the graph in FIG. 6, the addition of each terminating resistor 34a-d, 80 generally reduces the losses over the entire frequency range. Although the open-ended plating stubs 26a-d, 66 experience better losses at lower and higher frequencies, use of the terminating resistor 34a-d, 80 removes the stop frequency band of the signal existing in the open plating stubs 34a-d, 80 and provides about a 16 dB improvement for this particular example in the range of about 7 GHz to about 14 GHz, where a 50 ohm resistor was used to terminate each signal line to match the signal line impedance and source termination.

Selection of the terminating resistance value for each terminating resistor 34a-d, 80 may be based on the signal operating data rates and the quarter wavelength resonance associated with the plating stub lengths. As the resistance of the terminating resistor 34a-d, 80 increases, there may be less improvement near resonance frequency but instead less loss outside of the resonance frequency zone as a tradeoff. Therefore, the selection of a resistance value may mainly depend on whether the operating signal frequency range is within or outside the stop band centered at the resonance frequency of the plating stub 26a-d, 66. For example, if the frequency of the operating signal is near the plating stub resonance frequency, a resistance of 50 ohms or less may be more effective. If the operating signal frequency range is away from the stop band of the plating stubs 26a-d, 66, higher resistance values may be more effective.

Because of differences in length of each of the plating stubs 26a-d, a corresponding terminating resistor 34a, 34b, 34c, and 34d, each with a resistance corresponding to the length of the plating stub 26a-d may be used to terminate the plating stubs 26a-d. In some embodiments, the trace lengths of the plating stubs 26a-d may be characterized as having approximately the same length with the resistance values for each of the terminating resistors 34a-d being the same. Each of the terminating resistors 34a-d are connected to the closest one of the ground electrode pads 92a-c that is itself connected to ground. In some configurations, multiple plating stubs 26b, 26c may be connected to the same electrode pad 92b.

In an alternative embodiment and as visible in the semiconductor package 120 shown in FIG. 7, a plating stub 122 similar to plating stubs 26a-d may be located on a reverse side 125 of the interposer substrate 124 from the semiconductor element 126. In this embodiment, the semiconductor element 126 is mounted on the interposer substrate 124 and is connected to an electrode terminal (not shown) on the interposer substrate 124 by a bond wire (not shown) similar to the embodiments in FIGS. 1-4. The electrode terminal is connected by a signal line 128 to an electrode pad 130. The plating stub 122 is formed on the reverse side 125 and extends from electrode pad 132 to a peripheral edge 134 of the interposer substrate 124. Electrode pad 130 is connected to electrode pad 132 by a via 136, which electrically connects the signal line 128 to the plating stub 122.

The plating stub 122 may also be connected to a ground connection 138 through a terminating resistor 140. Similar to the embodiments discussed above, the terminating resistor 140 may be a surface mount resistor or, alternatively, may be a resistive film. The resistance of the terminating resistor 140 may generally be in the range of about 40 ohms to about 300 ohms, depending on the frequency range of the signals on the signal line 128 as similar to the embodiments described above. The terminating resistor 140 is generally mounted on the same side 125 of the interposer substrate as the plating stub 122. In this embodiment, the terminating resistor 140 is mounted on the reverse side of the interposer substrate 124 from the semiconductor element 126. The ground connection 138 for the resistor 140 may also be established through a ball grid array or by other known connection methods.

In an alternative embodiment, multiple plating stubs like plating stub 122 and multiple terminating resistors like terminating resistor 140 may be provided on the reverse side 125 of the interposer substrate 124.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A semiconductor package comprising:
an interposer substrate having a first side, a second side, a peripheral edge connecting the first side with the second side, a first signal line on the first side, and a first electrode pad on the first side;
a semiconductor element mounted on the first side of the interposer substrate, the semiconductor element connected with the first electrode pad by the first signal line;
a terminating resistor mounted on the interposer substrate; and
a plating stub on the interposer substrate, the plating stub having a first end portion terminating near the peripheral edge of the interposer substrate and a second end portion electrically connected to the first electrode pad, the first end portion of the plating stub electrically connected through the terminating resistor to an electrical ground.

2. The semiconductor package of claim 1, wherein the terminating resistor includes a first end electrically connected to the first end portion of the plating stub and a second end electrically connected to the electrical ground.

3. The semiconductor package of claim 1, wherein the semiconductor package further comprises:
a plurality of solder balls arranged in a ball grid array (BGA) on the second side of the interposer substrate;
a second electrode pad on the first side of the interposer substrate; and
a second signal line on the first side of the interposer substrate, the second signal line electrically connecting the second electrode pad with the second end of the resistor.

4. The semiconductor package of claim 3, further comprising:
a via extending through the interposer substrate from the first side to the second side, the via electrically connecting the second electrode pad with one of the plurality of solder balls in the ball grid array.

5. The semiconductor package of claim 1, wherein the resistor is a surface mounted resistor or a resistive film.

6. The semiconductor package of claim 1, wherein the resistor has a resistance in a range of 40 ohms to 300 ohms.

7. The semiconductor package of claim 1, wherein the plating stub is located on the first side of the interposer substrate.

8. The semiconductor package of claim 7, wherein the terminating resistor is mounted on the first side of the interposer substrate.

9. The semiconductor package of claim 1, wherein the plating stub is located on the second side of the interposer substrate, and further comprising:
a via extending from the first side through the interposer substrate to the second side, the via electrically connecting the first signal line with the plating stub.

10. The semiconductor package of claim 9, wherein the terminating resistor is mounted on the second side of the interposer substrate.

11. A system comprising:
a motherboard; and
a semiconductor package, the semiconductor package electrically connected to the motherboard and including:
an interposer substrate having a first side, a second side, a peripheral edge connecting the first side with the second side, a first signal line on the first side, and a first electrode pad on the first side;
a semiconductor element mounted on the first side of the interposer substrate, the semiconductor element connected with the first electrode pad by the first signal line;
a terminating resistor mounted on the interposer substrate; and
a plating stub on the interposer substrate, the plating stub having a first end portion terminating near the peripheral edge of the interposer substrate and a second end portion electrically connected to the electrode pad, the first end portion electrically connected through the terminating resistor to an electrical ground.

12. The system of claim 11, wherein the terminating resistor includes a first end electrically connected to the first end portion of the plating stub and a second end electrically connected to electrical ground.

13. The system of claim 11, wherein the terminating resistor a surface mounted resistor or a resistive film.

14. The system of claim 11, wherein the terminating resistor has a resistance in a range of 40 ohms to 300 ohms.

15. The system of claim 11, wherein the semiconductor package further comprises:
a plurality of solder balls arranged in a ball grid array (BGA) on the second side of the interposer substrate;
a second electrode pad on the first side of the interposer substrate; and
a second signal line on the first side of the interposer substrate, the second signal line electrically connecting the second electrode pad with the second end of the resistor.

16. The system of claim 11, wherein the plating stub is located on the first side of the interposer substrate and the terminating resistor is mounted on the first side of the interposer substrate.

17. The system of claim 11, wherein the plating stub is located on the second side of the interposer substrate, and further comprising:
a via extending from the first side of the interposer substrate to the second side of the interposer substrate, the via electrically connecting the first signal line with the plating stub.

18. A method of mounting a semiconductor element on an interposer substrate having a first side, a second side, a peripheral edge connecting the first side with the second side, a signal line on the first side and an electrode pad on the first side, the method comprising:
mounting a terminating resistor on the interposer substrate;
electrically connecting a first electrode pad on the interposer surface with the semiconductor element;
electrically connecting a first end portion of a plating stub to the electrode pad; and
electrically connecting a second end portion of the plating stub through the terminating resistor to an electrical ground.

19. The method of claim 18, wherein electrically connecting the second end portion through the terminating resistor comprises:
electrically connecting a first end of the terminating resistor to the second end portion of the plating stub; and
electrically connecting a second end of the terminating resistor to a conductor coupled with the electrical ground.
